(19) United States
(12) Patent Application Publication
(10) Pub. No.: US 2015/0123154 A1
(43) Pub. Date: May 7, 2015

(54) Light Emitting Diode Structure

(71) Applicant: Lextar Electronics Corporation, Hsinchu (TW)

(72) Inventors: Wen-Chieh HSU, Hsinchu City (TW); Tzong-Liang TSAI, Taichung City (TW)

(21) Appl. No.: 14/319,800

(22) Filed: Jun. 30, 2014

(30) Foreign Application Priority Data
Nov. 4, 2013 (TW) 102139967

(51) Int. Cl. H01L 33/42

(52) U.S. Cl. CPC H01L 33/42
USPC 257/98

(57) ABSTRACT

A light emitting diode structure includes a first type semiconductor layer, an illumination layer, a second type semiconductor layer, a plurality of first light extraction improvement structures and a transparent conductive layer. The illumination layer is disposed on the first type semiconductor layer. The second type semiconductor layer is disposed on the illumination layer, and the refractive index thereof is n1. The first light extraction improvement structures are disposed on the second type semiconductor layer, and the refractive index thereof is n2. The first light extraction improvement structures are spatially separated from each other, and each of them includes a slanted light outgoing surface oblique to the upper surface of the second type semiconductor layer. The transparent conductive layer conformably covers the first light extraction improvement structures and the second type semiconductor layer, and the refractive index thereof is n3, wherein n2>n3.

### RELATED APPLICATIONS

This application claims priority to Taiwan Application Serial Number 102139967, filed Nov. 4, 2013, which is herein incorporated by reference.

### BACKGROUND

1. Technical Field

Embodiments of the present invention relate to a lighting apparatus. More particularly, embodiments of the present invention relate to a light emitting diode structure.

2. Description of Related Art

Because the light emitting diode (LED) features advantages such as low power-consumption and small size, it has become one of the popular lighting devices and been widely applied in illumination and backlighting of display. A typical LED includes a N-type semiconductor layer, an active layer and a P-type semiconductor layer that are stacked sequentially. Both of the N-type semiconductor layer and the P-type semiconductor layer have an electrode thereon, so as to provide power to the N-type semiconductor layer and the P-type semiconductor layer.

The P-type semiconductor layer is made up of material with refractive index different from that of the transparent conductive material disposed on the P-type semiconductor layer. The refractive index difference is apt to render the total internal reflection, which confines the light within the LED and reduces the light extraction efficiency.

### SUMMARY

One aspect of the present invention is to improve the light efficiency.

In accordance with one embodiment of the present invention, a light emitting diode structure includes a first type semiconductor layer, an illumination layer, a second type semiconductor layer, a plurality of first light extraction improvement structures and a transparent conductive layer. The illumination layer is disposed on a part of the first type semiconductor layer and exposing another part of the first type semiconductor layer. The second type semiconductor layer is disposed on the illumination layer. The second type semiconductor layer has a refractive index n1. The first light extraction improvement structures are disposed on the second type semiconductor layer. Each of the first light extraction improvement structures has a refractive index n2. The first light extraction improvement structures are spatially separated from each other. Each of the first light extraction improvement structures has at least one oblique light outgoing surface oblique to an upper surface of the second type semiconductor layer. The transparent conductive layer conformably covers the first light extraction improvement structures and the second type semiconductor layer, and the transparent conductive layer having a refractive index n3, in which n2>n3.

In accordance with one embodiment of the present invention, a light emitting diode structure includes a first type semiconductor layer, an illumination layer, a second type semiconductor layer, a transparent conductive layer and a first light extraction improvement layer. The illumination layer is disposed on a part of the first type semiconductor layer and exposing another part of the first type semiconductor layer. The second type semiconductor layer is disposed on the illumination layer. The second type semiconductor layer has a refractive index n1. The transparent conductive layer is disposed on the second type semiconductor layer, and it has a refractive index n3. The first light extraction improvement layer is disposed on the transparent conductive layer, and it has a refractive index n2, in which n2>n3.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a light emitting diode structure in accordance with one embodiment of the present invention;

FIG. 2 is a cross-sectional view of the light emitting diode structure in accordance with the second embodiment of the present invention; and

FIG. 3 is a cross-sectional view of the light emitting diode structure in accordance with the third embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### First Embodiment

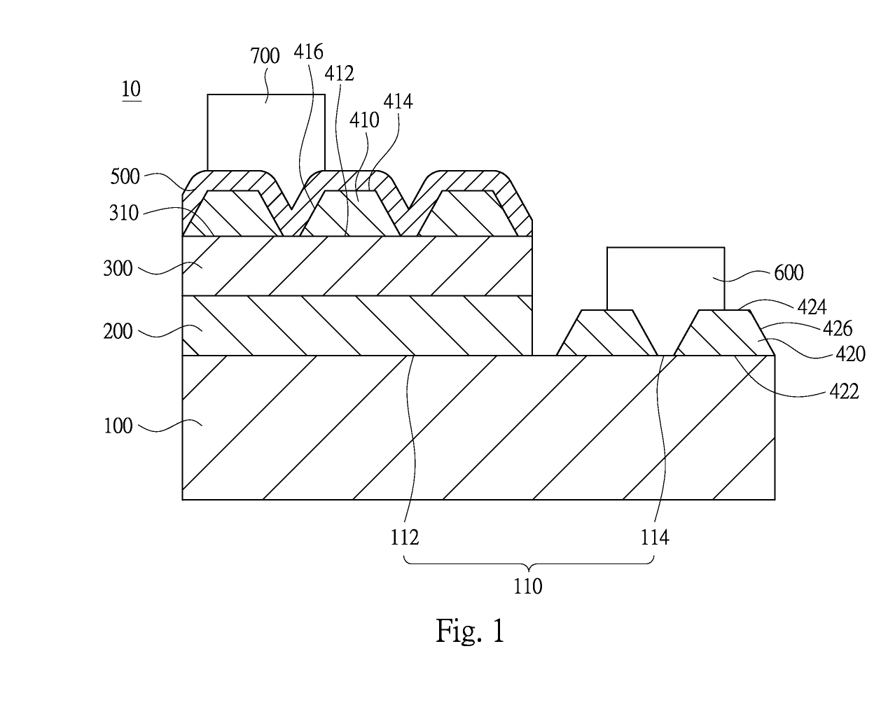

FIG. 1 is a cross-sectional view of a light emitting diode structure 10 in accordance with one embodiment of the present invention. As shown in FIG. 1, the light emitting diode 10 includes a first type semiconductor layer 100, an illumination layer 200, a second type semiconductor layer 300, a plurality of first light extraction improvement structures 410 and a transparent conductive layer 500. The illumination layer is disposed on a part of the first type semiconductor layer 100. The second type semiconductor layer 300 is disposed on the illumination layer 200. The second type semiconductor layer 300 has a refractive index n1. The first light extraction improvement structures 410 are disposed on the second type semiconductor layer 300. Each of the first light extraction improvement structures has a refractive index n2. Each of the first light extraction improvement structures 410 has at least one oblique light outgoing surface 416 oblique to an upper surface 310 of the second type semiconductor layer 300. The transparent conductive layer 500 conformably covers the first light extraction improvement structures 410 and the second type semiconductor layer 300. The transparent conductive layer 500 has a refractive index n3, in which n2>n3.

Because the first light extraction improvement structure 410 has a oblique light outgoing surface 416 in contact with the transparent conductive layer 500, when the light arrives at the oblique light outgoing surface 416, the incident angle of which the light goes into the transparent conductive layer 500 can be reduced, thereby preventing the total internal reflection, so that the light can easily go into the transparent conductive layer 500.

In the foregoing embodiment, the refractive index n2 of the first light extraction improvement structure 410 is greater than the refractive index n1 of the second type semiconductor layer 300. According to Snell's law, when the light goes from the illumination layer 200 to the interface between the second type semiconductor layer 300 and the first light extraction improvement structure 410, the critical angle increases. In other words, the total internal reflection at the foregoing interface requires greater incident angle. As a result, when the light goes from the illumination layer 200 to the interface between the second type semiconductor layer 300 and the first light extraction improvement structure 410, the chance that the total internal reflection occurs can be reduced, so that the light can go out of the upper surface 310 of the second type semiconductor layer 300 and into the first light extraction improvement structure 410 more easily.

Further, although the critical angle may be reduced because the refractive index n2 of the first light extraction improvement structure 410 is greater than the refractive index n3 of the transparent conductive layer 500, the incident angle is reduced when the light goes into the transparent conductive layer 500 through the oblique light outgoing surface 416. As a result, the chance that the total internal reflection occurs can still be reduced, and the light can still easily go into the transparent conductive layer 500. Moreover, the transparent conductive layer 500 conformably covers the first light extraction improvement structure 410, they can be formed in the same shape. Therefore, similar to the foregoing principle, even though the refractive index n3 of the transparent conductive layer 500 is greater than the refractive index of air (or additional encapsulating material, such as epoxy), the transparent conductive layer 500 can reduce the incident angle of which the light goes to air (or additional encapsulating material, such as epoxy) by the oblique surface thereof. As a result, the light emitting diode structure 10 can facilitate to emit light, thereby improving the light extraction efficiency.

In this embodiment, each of the first light extraction improvement structures 410 has a trapezoidal cross-section. In particular, one of the first light extraction improvement structure 410 has a bottom surface 412 and a top surface 414 opposite to the bottom surface 412. The bottom surface 412 contacts with the upper surface 310 of the second type semiconductor layer 300. The oblique light outgoing surface 416 connects the bottom surface 412 and the top surface 414. The area of the bottom surface 412 is not equal to the area of the top surface 414. For example, the area of the bottom surface 412 can be greater than the area of the top surface 414. In other words, the first light extraction improvement structure 410 tapers along the direction from the bottom surface 412 toward the top surface 414. In other embodiments, each of the first light extraction improvement structures 410 has, but is not limited to have, a triangular cross-section, a semicircle-shaped cross-section, or a rectangular cross-section.

In some embodiments, the illumination layer 200 exposes another part of the first type semiconductor layer 100. In other words, the upper surface 110 has a first zone 112 and a second zone 114 adjoined to the first zone 112. The first zone 112 is covered by the illumination layer 200, and the second zone 114 is not covered by the illumination layer 200. The light emitting diode structure 10 further includes a first electrode 600 and a second electrode 700. The first electrode 600 is formed on the exposed part of the first type semiconductor layer 100. In other words, the first electrode 600 is formed on the second zone 114 of the upper surface 110 of the first type semiconductor layer 100, so as to provide power to the first type semiconductor layer 100. The second electrode 700 is formed on the transparent conductive layer 500, so as to provide power to the second type semiconductor layer 300 through the transparent conductive layer 500.

In some embodiments, the first light extraction improvement structures 410 are separated from each other. In other words, the adjacent first light extraction improvement structures 410 are spaced apart and arranged at interval. A portion of the transparent conductive layer 500 is positioned in the gap between the adjacent first light extraction improvement structures 410 and contacts with the upper surface 310 of the second type semiconductor layer 300. As such, the transparent conductive layer 500 can be electrically connected between the second electrode 700 and the second type semiconductor layer 300, so as to allow the second electrode 700 to provide power to the second type semiconductor layer 300.

In some embodiments, the light emitting diode structure 10 includes a plurality of second light extraction improvement structures 420. The second light extraction improvement structures 420 are disposed on the exposed part of the first type semiconductor layer 100. Each of the second light extraction improvement structures 420 has a refractive index n4, in which n4>n1. The second light extraction improvement structures 420 are spatially separated from each other. In other words, adjacent second light extraction improvement structures 420 are arranged at an interval, and a portion of the first electrode 600 is positioned in the gap between the adjacent second light extraction improvement structures 420, such that the first electrode 600 is connected to the first type semiconductor layer 100.

In this embodiment, each of the second light extraction improvement structures 420 has a trapezoidal cross-section. In particular, one of the second light extraction improvement structure 420 has a bottom surface 422, a top surface 426 and an oblique light outgoing surface 426. The top surface 424 is opposite to the bottom surface 422. The bottom surface 422 contacts with the second zone 114 of the upper surface 110 of the first type semiconductor layer 300. The oblique light outgoing surface 426 connects the bottom surface 422 and the top surface 424. The area of the bottom surface 422 is not equal to the area of the top surface 424. For example, the area of the bottom surface 422 can be greater than the area of the top surface 424. In other words, the second light extraction improvement structure 420 tapers along the direction from the bottom surface 422 toward the top surface 424. In other embodiments, each of the second light extraction improvement structures 420 has, but is not limited to have, a triangular cross-section, a semicircle-shaped cross-section, or a rectangular cross-section.

In some embodiments, the first light extraction improvement structures 410 and the second light extraction improvement structures 420 are formed by oxide. For example, the oxide can be TiO₂, Ti₃O₅, MgO, Al₂O₃, HfO₂, ZrO₂, Y₂O₃ or any combination thereof.

In some embodiments, the first type semiconductor layer 100 is an N-type semiconductor layer. The second type semiconductor layer 300 is a P-type semiconductor layer. For example, the first type semiconductor layer 100 is formed by a nitride semiconductor doped with N-type impurity, such as n-GaN, which is formed by doping the group IVA elements, such as Silicon, in the pure GaN. The second type semiconductor layer 300 is a nitride semiconductor doped with P-type impurity, which is formed by doping the group IIA elements, such as Magnesium, in the pure GaN.

In some embodiments, the illumination layer 200 includes a plurality of quantum wells to assist the electrons and the electronic holes provided by the first type semiconductor layer 100 and the second type semiconductor layer 300 to combine therein.

In some embodiments, the material of the transparent conductive layer 500 can be, but is not limited to be, ITO or IZO.

### Second Embodiment

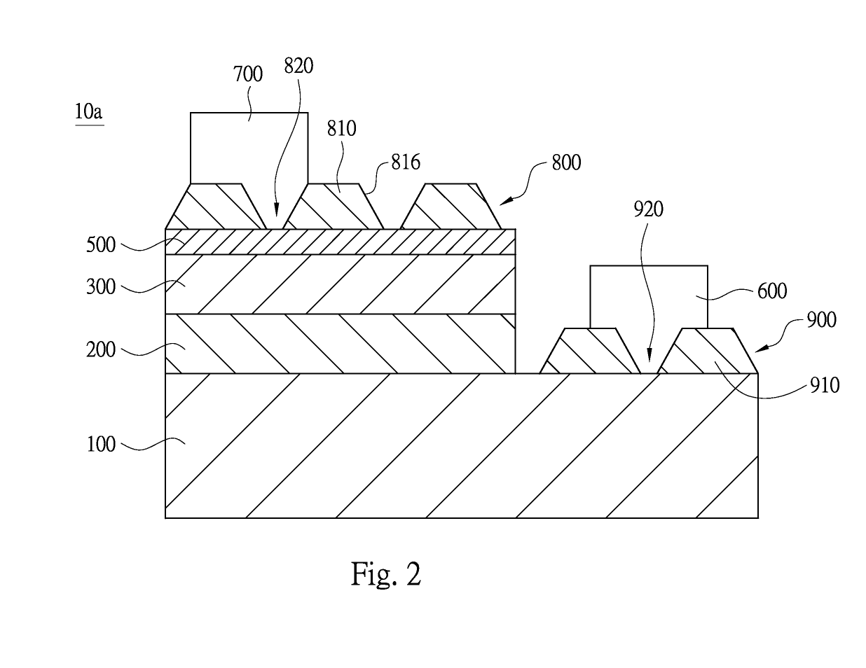

FIG. 2 is a cross-sectional view of the light emitting diode structure 10a in accordance with the second embodiment of the present invention. As shown in FIG. 2, the light emitting diode structure 10a includes a first type semiconductor layer 100, an illumination layer 200, a second type semiconductor layer 300, a transparent conductive layer 500 and a first light extraction improvement layer 800. The illumination layer 200 is disposed on a part of the first type semiconductor layer 100 and exposes another part of the first type semiconductor layer 100. The second type semiconductor layer 300 is disposed on the illumination layer 200. The second type semiconductor layer 300 has a refractive index n1. The transparent conductive layer 500 is disposed on the second type semiconductor layer 300, and it has a refractive index n3. The first light extraction improvement layer 800 is disposed on the transparent conductive layer 500, and it has a refractive index n2, in which n2>n1, and n2>n3. The first light extraction improvement layer 800 is formed by a plurality of light extraction improvement structures 810 spatially separated from each other. Each of the light extraction improvement structures 810 has an oblique light outgoing surface 816.

In the foregoing embodiment, the refractive index n2 of the first light extraction improvement layer 800 is greater than the refractive index n3 of the transparent conductive layer 500. According to Snell's law, when the light goes from the illumination layer 200 to the interface between the illumination layer 200 and the first light extraction improvement layer 800, the critical angle increases. In other words, the total internal reflection at the foregoing interface requires greater incident angle. As a result, when the light goes from the illumination layer 200 to the interface between the transparent conductive layer 500 and the first light extraction improvement layer 800, the chance that the total internal reflection occurs can be reduced, so that the light can go out of the transparent conductive layer 500 and into the first light extraction improvement layer 800 more easily.

Further, although the refractive index n2 of the first light extraction improvement layer 800 is greater than the refractive index of air (or additional encapsulating material), the incident angle of which the light goes to the oblique light outgoing surface 816 can still be reduced because the first light extraction improvement layer 800 has the oblique light outgoing surface 816. As a result, the chance that the total internal reflection occurs can still be reduced, and the light can still easily go into air (or additional encapsulating material).

In some embodiments, the light emitting diode structure 10a further includes a second light extraction improvement layer 900. The second light extraction improvement layer 900 is disposed on the exposed part of the first type semiconductor layer 100. The second light extraction improvement layer 900 is formed by a plurality of light extraction improvement structures 910 spatially separated from each other. The second light extraction improvement layer 900 has a refractive index n4, in which n4>n1.

In some embodiments, the shape of each of the light extraction improvement structures 810 and 910 is the same as which of the first light extraction improvement structures 410 and the second light extraction improvement structures 420. In other words, each of the light extraction improvement structures 810 and 910 has a trapezoidal cross-section, a triangular cross-section, a semicircle-shaped cross-section, or a rectangular cross-section.

In some embodiments, the light emitting diode structure 10a further includes a first electrode 600 and a second electrode 700. The first electrode 600 is formed on the exposed part of the first type semiconductor layer 100. The second electrode 700 is formed on the first light extraction improvement layer 800. The first light extraction improvement layer 800 has a first opening 820 exposing the transparent conductive layer 500. A portion of the second electrode 700 can be positioned in the first opening 820, such that the second electrode 700 is connected to the transparent conductive layer 500 through the first opening 820.

In some embodiments, the second light extraction improvement layer 900 has a second opening 920 exposing the first type semiconductor layer 100. A portion of the first electrode 600 can be positioned in the second opening 920, such that the first electrode 600 is connected to the first type semiconductor layer 100 through the second opening 920.

In some embodiments, the first light extraction improvement layer 800 and the second light extraction improvement layer 900 are formed by oxide. For example, the oxide can be TiO₂, Ti₃O₅, MgO, Al₂O₃, HfO₂, ZrO₂, Y₂O₃ or any combination thereof.

Other features in this embodiment are the same as which are described in the first embodiment, and therefore are not described repeatedly.

### Third Embodiment

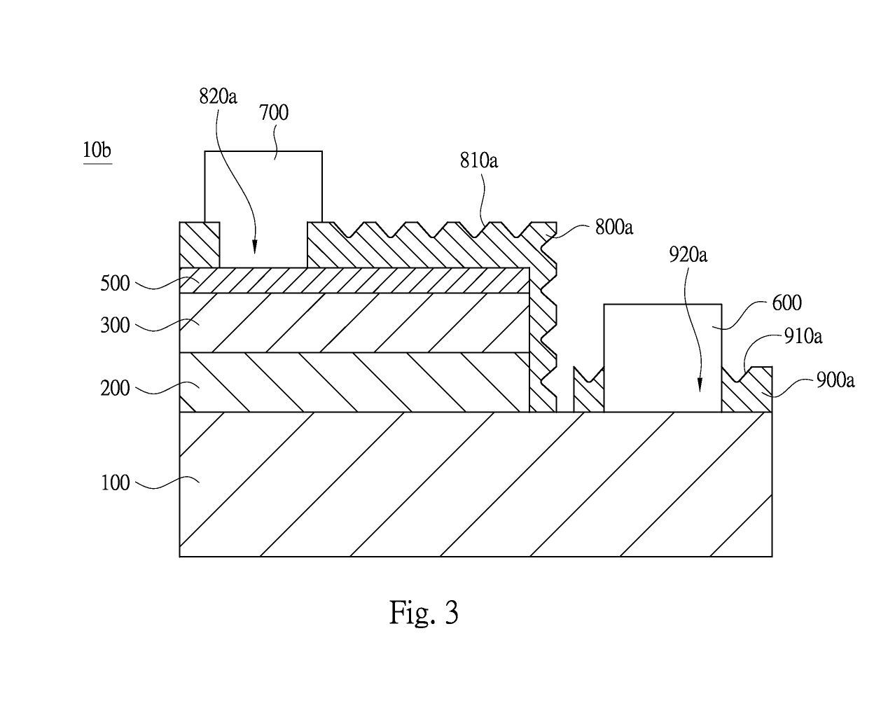

FIG. 3 is a cross-sectional view of the light emitting diode structure 10b in accordance with the third embodiment of the present invention. As shown in FIG. 3, the main difference between this embodiment and the second embodiment is that the first light extraction improvement layer 800a does not include structures separated from each other, and the second light extraction improvement layer 900a does not include structures separated from each other as well. The first light extraction improvement layer 800a has a plurality of uneven structures 810a connected to each other, or even formed integrally. The second light extraction improvement layer 900a has a plurality of uneven structures 910a connected to each other, or even formed integrally. The uneven structures 810a can reduce the incident angle of which the light arrives at the interface between the first light extraction improvement layer 800a and air (or additional encapsulating material), which reduces the chance that the total internal reflection occurs. Similarly, the uneven structures 910a can reduce the incident angle of which the light arrives at the interface between the second light extraction improvement layer 900a and air (or additional encapsulating material), which reduces the chance that the total internal reflection occurs.

Similar to the second embodiment, the first light extraction improvement layer 800a has a first opening 820a exposing the transparent conductive layer 500. A portion of the second electrode 700 can be positioned in the first opening 820a, such that the second electrode 700 is connected to the transparent conductive layer 500 through the first opening 820a.

Similar to the second embodiment, the second light extraction improvement layer 900a has a second opening 920a exposing the first type semiconductor layer 100. A portion of the first electrode 600 can be positioned in the second opening 920a, such that the first electrode 600 is connected to the first type semiconductor layer 100 through the second opening 920a.

Other features in this embodiment are the same as which are described in the first and second embodiments, and therefore are not described repeatedly.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode structure, comprising:
a first type semiconductor layer;
an illumination layer disposed on a part of the first type semiconductor layer and exposing another part of the first type semiconductor layer;
a second type semiconductor layer disposed on the illumination layer, the second type semiconductor layer having a refractive index n1;
a plurality of first light extraction improvement structures disposed on the second type semiconductor layer, each of the first light extraction improvement structures having a refractive index n2, the first light extraction improvement structures being spatially separated from each other, and each of the first light extraction improvement structures having at least one oblique light outgoing surface oblique to an upper surface of the second type semiconductor layer; and
a transparent conductive layer conformably covering the first light extraction improvement structures and the second type semiconductor layer, the transparent conductive layer having a refractive index n3, wherein n2>n3.

2. The light emitting diode structure of claim 1, wherein n2>n1.

3. The light emitting diode structure of claim 1, further comprising a first electrode formed on the exposed part of the first type semiconductor layer and a second electrode formed on the transparent conductive layer.

4. The light emitting diode of claim 3, further comprising a plurality of second light extraction improvement structures disposed on the exposed part of the first type semiconductor layer, wherein each of the second light extraction improvement structures has a refractive index n4, and the second light extraction improvement structures are spatially separated from each other, such that the first electrode is connected to the first type semiconductor layer, wherein n4>n1.

5. The light emitting diode of claim 4, wherein each of the first light extraction improvement structures and each of the second light extraction improvement structures have trapezoidal cross-sections, triangular cross-sections, semicircle-shaped cross-sections, or rectangular cross-sections.

6. The light emitting diode structure of claim 5, wherein the first light extraction improvement structures and the second light extraction improvement structures are formed by oxide.

7. The light emitting diode structure of claim 6, wherein the oxide is TiO₂, Ti₃O₅, MgO, Al₂O₃, HfO₂, ZrO₂, Y₂O₃ or any combination thereof.

8. The light emitting diode structure of claim 1, wherein the first type semiconductor layer is an N-type semiconductor layer, and the second type semiconductor layer is a P-type semiconductor layer.

9. A light emitting diode structure, comprising:
a first type semiconductor layer;
an illumination layer disposed on a part of the first type semiconductor layer and exposing another part of the first type semiconductor layer;
a second type semiconductor layer disposed on the illumination layer, the second type semiconductor layer having a refractive index n1;
a transparent conductive layer disposed on the second type semiconductor layer, the transparent conductive layer having a refractive index n3; and
a first light extraction improvement layer disposed on the transparent conductive layer, the first light extraction improvement layer having a refractive index n2, wherein n2>n3.

10. The light emitting diode structure of claim 9, wherein n2>n1.

11. The light emitting diode structure of claim 9, further comprising a first electrode formed on the exposed part of the first type semiconductor layer and a second electrode formed on the first light extraction improvement layer, wherein the first light extraction improvement layer has a first opening exposing the transparent conductive layer, such that the second electrode is connected to the transparent conductive layer through the first opening.

12. The light emitting diode structure of claim 11, further comprising a second light extraction improvement layer disposed on the exposed part of the first type semiconductor layer, wherein the second light extraction improvement layer has a refractive index n4, and the second light extraction improvement layer has a second opening exposing the first semiconductor layer, such that the first electrode is connected to the first type semiconductor layer through the second opening, wherein n4>n1.

13. The light emitting diode structure of claim 12, wherein the first light extraction improvement layer and the second light extraction improvement layer are both formed by a plurality of light extraction improvement structures spatially separated from each other.

14. The light emitting diode structure of claim 13, wherein each of the light extraction improvement structures has a trapezoidal cross-section, a triangular cross-section, a semicircle-shaped cross-section, or a rectangular cross-section.

15. The light emitting diode structure of claim 12, wherein the first light extraction improvement layer and the second light extraction improvement layer have a plurality of uneven structures.

16. The light emitting diode structure of claim 12, wherein the first light extraction improvement layer and the second light extraction improvement layer are formed by oxide.

17. The light emitting diode structure of claim 16, wherein the oxide is TiO₂, Ti₃O₅, MgO, Al₂O₃, HfO₂, ZrO₂, Y₂O₃ or any combination thereof.

18. The light emitting diode structure of claim 9, wherein the first type semiconductor layer is an N-type semiconductor layer, and the second type semiconductor layer is a P-type semiconductor layer.
